(19) United States
(12) Patent Application Publication
(10) Pub. No.: US 2017/0313828 A1
(43) Pub. Date: Nov. 2, 2017

(54) IN SITU-FORMING OF DENDRIMER HYDROGELS USING MICHAEL-ADDITION REACTION

(71) Applicant: Virginia Commonwealth University, Richmond, VA (US)

(72) Inventors: Juan Wang, Richmond, VA (US); Hu Yang, Glen Allen, VA (US)

(73) Assignee: Virginia Commonwealth University, Richmond, VA (US)

(21) Appl. No.: 15/584,622

(22) Filed: May 2, 2017

Related U.S. Application Data
(60) Provisional application No. 62/330,511, filed on May 2, 2016.

(51) Int. Cl. C08J 3/24; C08G 83/00; C08G 73/02; H01J 37/28; G01N 30/02; G01R 33/46

(52) U.S. Cl. CPC C08J 3/246; C08G 83/004; C08G 73/028; C08G 2210/00; G01N 2030/027; G01R 33/46; H01J 37/28

(57) ABSTRACT

A method of forming a dendrimer hydrogel, the method comprising providing one or more amine end-functioned polyamidoamine (PAMAM) as a first reactant; providing one or more small molecule, polymer, hyperbranched molecule, or dendrimer as a second reactant, wherein the second reactant comprises one or more acrylate groups; and reacting the first reactant with the second reactant by way of conjugate addition. Compositions obtained thereby and uses thereof are also provided.

### RELATED APPLICATIONS

This application claims the benefit of U.S. Provisional Application No. 62/330,511, filed May 2, 2016, the entire contents of which are hereby incorporated by reference.

### STATEMENT OF GOVERNMENT INTEREST

This invention was made with government support under Grant Nos. R01EY024072 and R01DE024381 awarded by the National Institute of Health and under Grant No. CBET0954957 awarded by the National Science Foundation. The government has certain rights in the invention.

### FIELD OF THE INVENTION

This invention relates to the field of chemistry and in particular methods of forming polyamidoamine (PAMAM) dendrimer hydrogels using Michael-addition chemistry. The dendrimer hydrogels have potential in biomedical applications.

### BRIEF DESCRIPTION OF THE FIGURES

FIG. 1 shows one example of fabrication of polyamidoamine dendrimer hydrogels by way of Michael-addition and one example of a biomedical application as a drug delivery system.

FIG. 2 presents ¹H NMR spectra of PAMAM G5 dendrimers with different degrees of acetylation in D20.

FIG. 3 presents HPLC spectra detected at 220 rim of PAMAM G5 dendrimers with different degrees of acetylation (the elution is 25 vol % of acetonitrile, 75 vol % of water and 0.05 vol % of trifluoroacetic acid).

FIG. 4 presents Zeta potentials of PAMAM G5 dendrimers with different degrees of acetylation.

FIG. 5 presents in graphical form a summary of the dendrimer hydrogels fabricated from G5 PAMAM with different degrees of acetylation under different concentrations. Y-axis shows the weight % of dendrimer in H2O. Molar ratio of PEGDA acrylate : PAMAM amine is 1:1.

FIG. 6 presents SEM images and photos of invert gels fabricated from PAMAM G5-(NH₂)₁₂₈ dendrimer and PEG diacrylate575. The concentration of dendrimer is 20 wt % (A), 10 wt % (B), and 5 wt % (C). The gelation solvent is water and gelation temperature is 25° C. The feed ratio of the amine groups and acrylate groups is 1 to 1.

FIG. 7 presents data from rheological experiments of the dendrimer hydrogel of 5 wt % PAMAM G5-(NH₂)₁₂₈ dendrimer and PEG diacrylate575 with the feed ratio of the amine groups and acrylate groups is 1 to 1: A) the evolution of the time-dependent elastic (G′) and viscous (G″) modulus from a time sweep, B) G′ and G″ modulus as a function of strain, and C) G′ and G″ modulus as a function of frequency.

FIG. 8 presents swelling dynamics at 25° C. of dendrimer hydrogels fabricated from 20 wt % and 10 wt % of PAMAM G5-(NH₂)₁₂₈ dendrimer and PEG diacrylate575 with the feed ratio of the amine groups and acrylate groups is 1 to 1.

FIG. 9 presents graphically release of the fluorouracil from the dendrimer hydrogels of 1 wt % of PAMAM G5-(NH₂)₁₂₈ dendrimer and PEG diacrylate575 with the feed ratio of the amine groups and acrylate groups is 1 to 1.

FIG. 10 presents ¹H NMR spectrum of the G3.5-(PEG1500-acrylate)₂₇ in D₂O.

FIG. 11 presents an image of the invert hydrogel formed from G3.5-(PEG1500-acrylate)₂₇ and PAMAM G3 dendrimer with the feed ratio of the amine groups and acrylate groups is 1 to 1.

FIG. 12 presents solidification kinetics of dendrimer hydrogels as a function of degree of acetylation (G5-G5-Ac axis) and dendrimer concentration (in wt. %).

FIG. 13 shows effects of acetylation on morphologies and swelling of dendrimer hydrogels. (A) SEM micrographs. (B) Swelling kinetics in pH 7.4 PBS at 37° C. (C) Disintegration in pH 7.4 PBS at 37° C.

FIG. 14 presents rheological properties of dendrimer hydrogels. (A) Oscillatory time sweep. (B) Oscillatory frequency sweep. represents storage modulus (G′) and ◯ represents loss modulus (G″).

FIG. 15 shows solidified dendrimer hydrogel supports cell adherence and proliferation. Top panel: NIH3T3 cells were directly cultured on tissue culture polystyrene plate (TCPS) for 24 h and 48 h, respectively. Middle panel: NIH3T3 cells were cultured on FITC-labeled DH-G5-Ac⁶⁴-10% (gel/FITC) for 24 h and 48 h, respectively. Bottom panel: The letters written with FITC-labeled DH-G5-Ac⁶⁴-10% and incubated in cell culture medium for 24 h and 48 h, respectively. NIH3T3 cells were counterstained with DAPI (blue). Scale bar: 100 μm.

FIG. 16 presents characterization and in vitro assessment of liquid dendrimer hydrogel DH-G5-0.5% for drug delivery. (A) Oscillatory amplitude sweep of DH-G5-0.5%. represents storage modulus (G′) and ◯ presents loss modulus (G″). (B) SEM micrograph of DH-G5-0.5%. (C) Cumulative release of 5-FU from DH-G5-0.5% in PBS buffer pH=7.4 (n=3) at 37° C. (D) Cytotoxicity assay of DH-G5-0.5% (n=6). * Statistically significant.

FIG. 17 presents in vivo antitumor assessment of 5-FU/DH-G5-0.5%. (A) Relative tumor volume change during the treatment. (B) Mice body weight change during the treatment. (C) Images of extracted tumors after the treatment. (D) H&E staining of tumor tissues after the treatment (magnification 200×). * Statistically significant.

FIG. 18 presents one representation of the method of preparation and hydrogels comprising dendrimer and PEG diacrylate prepared by way of Michael-addition chemistry.

FIG. 19 presents one representation wherein the G5 PAMAM dendrimer is first reacted with acetic anhydride in the presence of triethylamine in methanol for 24 hours.

FIG. 20 presents synthetic routes for G3.5-PEG-acrylate.

FIG. 21 shows acetylated G5 (G%-Ac) synthesis and aza-Michael addition reaction of G5 or G5-Ac with PEG DA.

FIG. 22 presents an embodiment in which hydroxyl PEG acrylate (1 equiv) was dissolved in tetrahydrofuran (THF), followed by addition of 4-nitrophenol chloroformate (NPC) (1.5 equiv) and triethylamine (TEA) (20 equiv).

### SUMMARY OF THE INVENTION

One embodiment provides a method of forming a dendrimer hydrogel, the method comprising:
providing one or more amine end-functioned polyamidoamine (PAMAM) as a first reactant;
providing one or more small molecule, polymer, hyperbranched molecule, or dendrimer as a second reactant, wherein the second reactant comprises one or more acrylate groups; and
reacting the first reactant with the second reactant by way of conjugate addition.

Another embodiment provides a method of forming a dendrimer hydrogel, the method comprising:
providing one or more amine end-functioned polyamidoamine (PAMAM);
providing one or more poly(ethylene glycol) (PEG) diacrylate; and
reacting the PAMAM with the PEG diacrylate by way of conjugate addition.

Another embodiment provides a method of forming a dendrimer hydrogel, the method comprising:
providing one or more first reactant which is a polyamidoamine (PAMAM) chosen from PAMAM G5-(NH2)x-(Ac)128-x, wherein x is a number ranging from 1 to 128;
providing one or more second reactant which is a compound comprising one or more acrylate groups; and
performing a conjugate addition reaction with the first and second reactant to produce a dendrimer hydrogel.

Another embodiment provides a method of forming a dendrimer hydrogel, the method comprising:
reacting in the presence of water at a temperature of about 25° C.:
   polyamidoamine PAMAM G3-(NH2)32; with
   PAMAM G3.5-(PEG1500-acrylate)27; to form a dendrimer hydrogel.

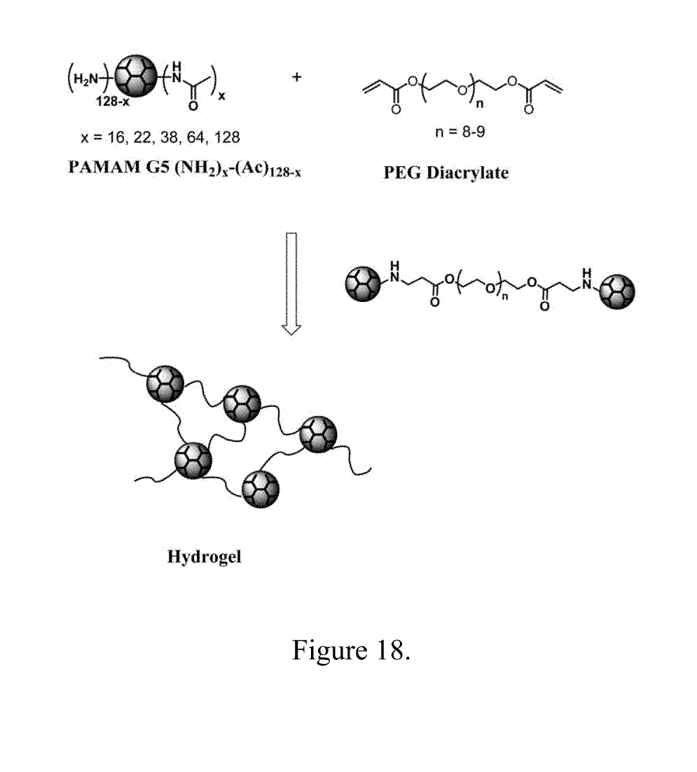

Another embodiment provides a method of treating cancer, the method comprising administering to a patient a compound, such as a drug, wherein the drug is administered using a dendrimer hydrogel as a drug delivery vehicle and the hydrogel comprises the structure shown in FIG. 18.

Another embodiment provides a composition comprising:
a compound, such as a drug; and
a dendrimer hydrogel as a drug delivery vehicle for the drug, wherein the hydrogel comprises the structure shown in FIG. 18.

Another embodiment provides a composition, such as a dendrimer hydrogel, prepared by process comprising:
providing one or more amine end-functioned polyamidoamine (PAMAM) as a first reactant;
providing one or more small molecule, polymer, hyperbranched molecule, or dendrimer as a second reactant, wherein the second reactant comprises one or more acrylate groups; and
reacting the first reactant with the second reactant by way of conjugate addition, wherein said reacting is carried out without the use of a catalyst or photoinitiator.

Another embodiment provides a composition, such as a dendrimer hydrogel, prepared by process comprising:
providing one or more amine end-functioned polyamidoamine (PAMAM) dendrimer;
providing one or more poly(ethylene glycol) (PEG) diacrylate; and
reacting the PAMAM with the PEG diacrylate by way of conjugate addition, wherein said reacting is carried out without the use of a catalyst or photoinitiator.

Another embodiment provides a composition, such as a dendrimer hydrogel, prepared by process comprising:
providing one or more first reactant which is a polyamidoamine (PAMAM) chosen from PAMAM G5-(NH2)x-(Ac)128-x, wherein x is a number ranging from 1 to 128;
providing one or more second reactant which is a compound comprising one or more acrylate groups or diacrylate groups; and
performing a conjugate addition reaction with the first and second reactant to produce a dendrimer hydrogel, wherein said reaction is carried out without the use of a catalyst or photoinitiator.

Another embodiment provides a composition, such as a dendrimer hydrogel, prepared by process comprising:
reacting in the presence of water at a temperature of about 25° C.:
   polyamidoamine PAMAM G3-(NH2)32; with
   PAMAM G3.5-(PEG1500-acrylate)27;
wherein said reacting is carried out without the use of a catalyst or photoinitiator.

Another embodiment provides a composition, such as a dendrimer hydrogel, prepared by process comprising:
reacting in the presence of water at a temperature of about 25° C.:
   polyamidoamine PAMAM G3-(NH2)ₚ; with
   PAMAM G3.5-(PEG-acrylate)ₚ′;
wherein p and p′ each independently range from 1-64, and wherein said reacting is carried out without the use of a catalyst or photoinitiator.

Another embodiment provides a composition, comprising:
one or more amine end-functioned polyamidoamine (PAMAM) dendrimers, one or more carboxylic acid end-functioned polyamidoamine (PAMAM) dendrimers, or a combination thereof; and
one or more poly(ethylene glycol) (PEG) diacrylate, PEG monoacrylate, or hydroxyl-PEG monoacrylate, or a combination thereof;
optionally, one or more reaction product thereof, the reaction product resulting from a conjugate addition and without the use of catalyst or photoiniator.

Another embodiment provides a composition, comprising:
a conjugate addition reaction product, obtained without the use of catalyst or photoinitiator, of:
one or more amine end-functioned polyamidoamine (PAMAM) dendrimer; and
one or more poly(ethylene glycol) (PEG) diacrylate.

One embodiment provides an injectable in situ-forming polyamidoamine (PAMAM) dendrimer hydrogels using highly efficient aza-Michael addition reaction. The aza-Michael addition reaction is efficient in coupling nitrogen nucleophiles to α,β-unsaturated carbonyl compounds. The present inventors have successfully, and surprisingly, adopted the aza-Michael addition reaction to construct injectable dendrimer hydrogels by reacting PAMAM dendrimers carrying primary surface amines to polyethylene glycol diacrylate (PEG-DA). It is the strong nucleophilicity of primary amines that enables the reaction to proceed in aqueous solutions without using base catalysts. The combination of the dendritic structure of PAMAM dendrimer and the efficient aza-Michael addition yields unique in situ forming dendrimer hydrogels. The high degree of functionality of PAMAM dendrimer offers a convenient way to modulate dendrimer hydrogel properties. The inventors have found that PAMAM dendrimer G5 as the underlying core can have its surface charges tuned via various degrees of acetylation using acetic anhydride. The inventors systematically investigated in situ gelling kinetics, network structures and swelling kinetics of the dendrimer hydrogels prepared using aza-Michael addition reaction of G5 and acetylated G5 with short-chain PEG DA (Mₙ=575 g/mol). The biocompatibility and the ability of the forming dendrimer hydrogels to support cell adhesion were also studied. One potential application of injectable dendrimer hydrogels is localized anticancer drug delivery. Anticancer drugs can be highly localized to attack tumor cells more directly while avoiding systemic toxicity effects. Intratumoral formulation of injectable dendrimer hydrogel loaded with fluorouracil (5-FU) was tested in a xenograft mouse model of head and neck cancer.

### BRIEF DESCRIPTION OF THE SEVERAL EMBODIMENTS

In one embodiment, the hydrogels can be obtained by mixing the amine end-functioned PAMAM with the acrylate groups of poly(ethylene glycol) (PEG) diacrylate under different feed ratios in aqueous solution. No catalyst is needed for the gelation. One or more solvents and/or drugs or other additives may optionally be present.

In another embodiment, the hydrogels can be obtained by mixing (a) carboxylic acid end-functioned PAMAM dendrimers that have been reacted with hydroxyl-PEG monoacrylates with (b) amine end-functioned PAMAM dendrimers and (c) polyethylene glycol) (PEG) diacrylate under different feed ratios in aqueous solution. No catalyst is needed for the gelation. One or more solvents and/or drugs or other additives may optionally be present.

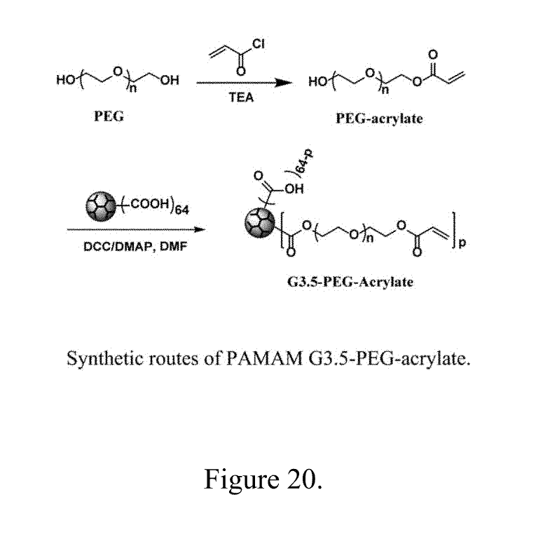

In another embodiment, the hydrogels can be obtained by mixing (a) amine end-functioned PAMAM dendrimers that have been reacted with hydroxyl-PEG monoacrylates (that have been first reacted with NPC/TEA for example such as shown in FIG. 20) with (b) amine end-functioned PAMAM dendrimers and, optionally (c) poly(ethylene glycol) (PEG) diacrylate under different feed ratios in aqueous solution. No catalyst is needed for the gelation. One or more solvents and/or drugs or other additives may optionally be present.

It should be clear that the x and 128-x subscripts for the respective H2N- and —NH(CO)CH₃ groups on the PAMAM dendrimers are interchangeable depending on the context, for example, such as shown in FIGS. 18, 19, 21 and 22 and elsewhere herein.

Preferably, the conjugate addition is aza Michael addition or Michael addition.

In the hydroxyl-PEG acrylate, or PEG diacrylate, the n value in the —(CH₂—CH₂—O)ₙ— portion (that is, the ethylene glycol portion) such as shown, for example, in FIGS. 18 and 20 is not particularly limited, and may suitably range from 1-20. This range includes all values and subranges therebetween, including 1, 2, 3, 4, 5, 6, 7, 9, 10, 11, 12, 13, 14, 15, 16, 17, 18, 19 and 20.

In one embodiment, the —NH(CO)CH₃ group on the PAMAM is unreactive with the acrylate.

The p subscript in the G3.5 dendrimers herein may suitably range from 1 to 64. This range includes all values and subranges therebetween, including for example from 2 to 4, or from 6 to 12, or from 8 to 20, or from 10 to 32, or from 18 to 44, or from 24 to 36, or from 28 to 48, or from 38 to 56, or from 52 to 64, and so on.

More specifically, the in-situ gels can be fabricated by reacting amine end-functioned PAMAM with the acrylate groups of small molecules, polymers with different molecular weights and/or different molecular architectures, hyperbranched molecules, and dendrimers by way of a conjugate addition. In one embodiment, the amine end-functioned PAMAM is reacted with the acrylate groups of poly(ethylene glycol) (PEG) diacrylate by way of Michael-addition, a conjugate addition reaction which is highly efficient especially in protic solvents, such as water, even at room temperature. The Michael-addition chemistry between primary amine and acrylate groups can be used to construct a series of dendrimer hydrogels. The Michael-addition chemistry can efficiently couple electron poor olefins with a vast array of nucleophiles.

The first reactant and the second reactant may be suitably reacted in the presence of a protic solvent or an aprotic solvent, or a combination thereof Non-limiting examples of solvents include water, saline, physiological saline, cell culture medium, DMSO, methanol, ethanol, dichloromethane, ether, hexane, chloroform, acetone, tetrahydrofuran, or any combination thereof.

The concentration of reactants and/or hydrogel in the solvent is not particularly limiting, and may suitably range from 0.01 to 100% by weight. This range includes all amounts and subranges therebetween, including 0.01, 0.02, 0.03, 0.04, 0.05, 0.06, 0.07, 0.08, 0.09, 0.1, 0.1, 0.2, 0.3, 0.4, 0.5, 0.6, 0.7, 0.8, 0.9, 0.1, 1, 2, 3, 4, 5, 6, 7, 8, 9, 10, 15, 20,25, 30, 35, 40, 45, 50, 55, 60, 65, 70, 75, 80, 85, 90, 95, and 100% by weight, or any combination thereof

The first reactant and the second reactant may be suitably reacted at a temperature ranging from −20-50° C. This range includes all values and subranges therebetween, including −20, −15, −10, −5, −1, 0, 1, 2, 3, 4, 5, 6, 7, 8, 9, 10, 15, 20, 25, 30, 35, 40, 45, and 50° C.

The first reactant and the second reactant may be suitably reacted by Michael addition chemistry, sometimes referred to herein as aza Michael addition chemistry, without the addition of catalyst, photoinitiator, UV-light, UV-initiated crosslinking or the like. Accordingly, in one embodiment, the composition, injectable composition, or hydrogel, or combination thereof does not include a catalyst or photoinitiator, and is prepared without the use of UV-light or UV-initiated crosslinking.

In one embodiment, the composition, hydrogel, or combination thereof, with or without solvent, drug or other additive, or combination thereof is injectable. Preferably, injectable means having sufficient liquid flow or viscosity such that it is capable of or amenable to being injected or administered with a syringe, PICC line, catheter, IV line, or similar. The composition may be injected at any point during the reaction process or along the reaction time coordinate, for example at any point during the gelation or solidification. In some embodiments, the composition is injected, optionally with a drug or other additive, and the corresponding hydrogel forms thereafter in-situ.

Rheological experiments show that an elastic three-dimensional network fabricates within 10 minutes after mixing PAMAM with PEG diacrylate even at very low concentrations (1 wt %). The high efficiency of gelation can be attributed to the highly dense primary amine groups on the surface of PAMAM dendrimers in addition to the high reactivity of Michael-addition between amine and acrylate groups.

The PAMAM dendrimer is selected as the main structural component due to its hydrophilicity and multi-functionality. The newly constructed dendrimer hydrogels possess tunable network structure and controlled swelling properties through the modulation of dendrimer surface.

Embodiments of the invention provide for a rapid forming dendrimer hydrogel using Michael-addition between primary amine and acrylate groups. This gelation method is highly efficient and does not require use of a catalyst.

One representation of the method of preparation and hydrogels comprising dendrimer and PEG diacrylate prepared by way of Michael-addition chemistry is shown in FIG. 18.

This new type of hydrogel has controlled mechanical property. network structure, and swelling behavior. The hydrogel can be further modulated to obtain stimuli-sensitive properties to respond to pH, light, enzyme, heat, etc. This hydrogel has great potential for biomedical applications, including for example tissue engineering, controlled drug delivery, cell adhesion, tissue engineering, etc.

For example, because of the high efficient gelation rate, this hydrogel network is able to serve as a depot for drug delivery. Cells can be encapsulated and serve as a tissue regeneration platform.

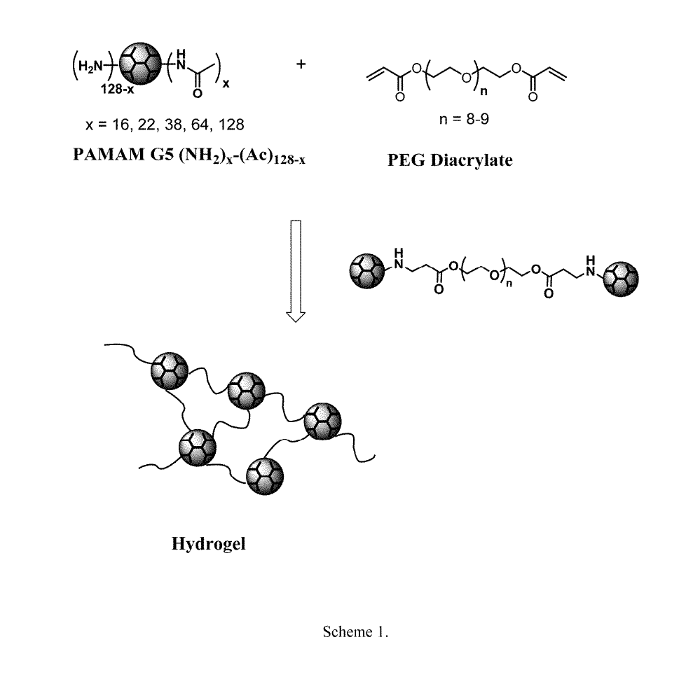

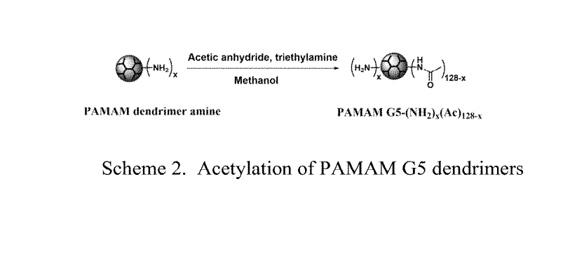

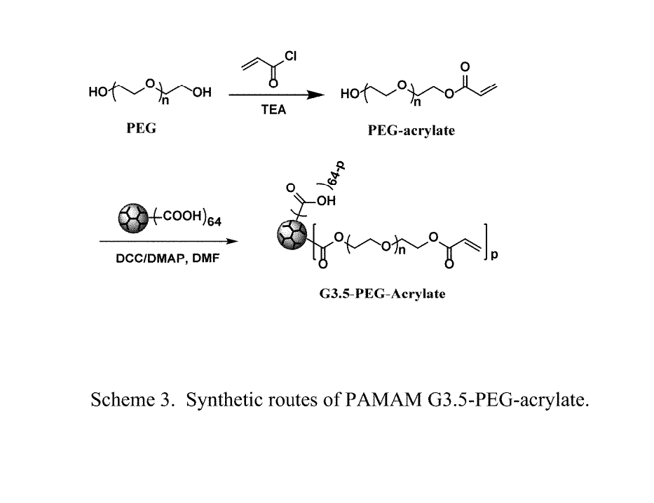

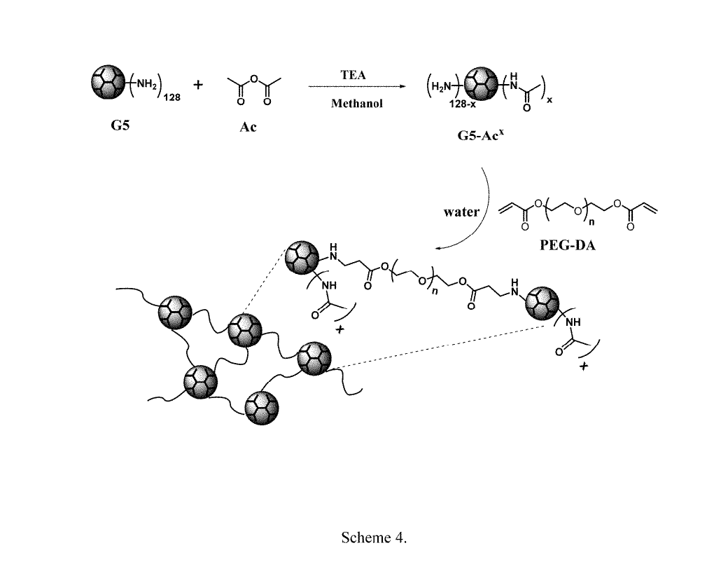

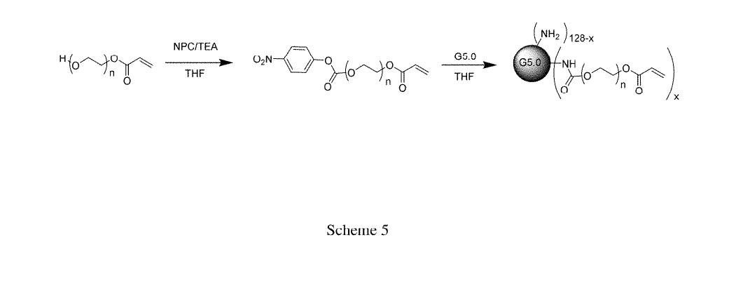

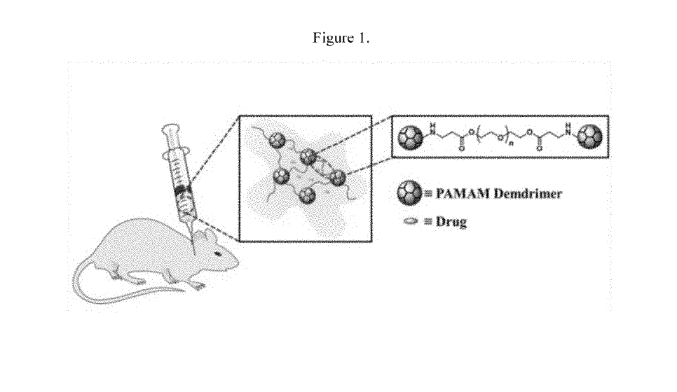

This rapid cross-linked hydrogel can serve as drug delivery system, wherein anti-cancer drugs can be in-situ embedded in the network of the hydrogel and injected to the tumor, such as shown in FIG. 1.

Dendrimers are uniform branched macromolecules with well-defined sizes and architectures, highly symmetrical geometry, and a large number of functional groups. The multi-functionality makes dendrimer an ideal cross-linking agent for producing three-dimensional networks.

Some examples, which are not intended to be limiting, of components of dendrimer hydrogels are listed in Table 1.

TABLE 1
Exemplary components of dendrimer hydrogels.

| Dendrimer | Component I with | Component II with |
|---|---|---|
| Hydrogel | amine groups | acrylate groups |
| #1 | PAMAM G5-(NH2)16-(Ac)112 | PEG diacrylate575 |
| #2 | PAMAM G5-(NH2)22-(Ac)106 | PEG diacrylate575 |
| #3 | PAMAM G5-(NH2)38-(Ac)90 | PEG diacrylate575 |
| #4 | PAMAM G5-(NH2)64-(Ac)64 | PEG diacrylate575 |
| #5 | PAMAM G5-(NH2)128 | PEG diacrylate575 |
| #6 | PAMAM G3-(NH2)32 | PAMAM G3.5- |
| | | (PEG1500-acrylate)27 |

Dendrimer hydrogels can be fabricated from generation 5 polyamidoamine (G5 PAMAM) dendrimers and poly(ethylene glycol) diacrylate with a molecular weight of 575 (PEG diacrylate575). The gelation solvent is water and the gelation temperature is 25° C. The feed ratio of the amine groups and acrylate groups is 1 to 1.

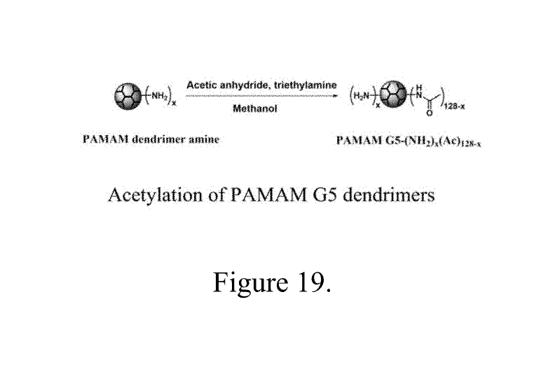

The G5 PAMAM dendrimer is first reacted with acetic anhydride in the presence of triethylamine in methanol for 24 hours (FIG. 19). Any PAMAM dendrimer can be used. Exemplified in this disclosure are G5 PAMAM dendrimers comprising from 0-128 amine groups, or conversely 128-0 Ac groups as the case may be. For example, as shown in FIG. 19, x is from 1 to 128, such as from 2 to 4, or from 6 to 12, or from 8 to 20, or from 10 to 32, or from 18 to 44, or from 24 to 36, or from 28 to 48, or from 38 to 56, or from 52 to 64, or from 56 to 68, or from 60 to 80, or from 72 to 90, or from 84 to 96, or from 88 to 112, or from 92 to 118, or from 98 to 128, or from 110 to 124, and so on). Intensive dialysis in deionized water and lyophilization are then carried out to obtain the pure products.

In one embodiment, the composition, injectable composition, or hydrogel, or combination thereof may include one or more active drugs or other additives or active substances. Non-limiting examples of active drugs, other additives and active substances include drugs, such as (S)-(+)-Camptothecin, 5-Fluorouracil (5-FU), 6-Mercaptopurine (6-MP), Abatacept, Abiraterone, Actinomycin-D, Altretamine, Ancef, Apatinib, Axitinib, Bevacizumab, Bleomycin, Borterzomib, Bortezomib, Brimonidine, Busulfan, Capecitabine, Carboplatin, Carmustine, Ceftazidime, Cefuroxime, Cetuximab, Cevimeline, Chidamide, Chlorambucil, Cisplatin, Crizotinib, Curcumin, Cyclophosphamide, Cyclosporine, Cytarabine, Cytotoxan, Dacarbazine, Dasatinib, Daunorubicin, Docetaxel, Doxorubicin, Epirubicin, Erlotinib, Erythromycin, Estramustine, Etopisode, Everolimus, Examethasone, Floxuridine, Fludarabine, Folic Acid, Gefitinib, Gemcitabine, Gleevec, Hydroxyurea, Ibrutinib, Icotinib, Idarubicin, Imatinib, Insulin, Irinotecan, Ixabepilone, KU 55933, KU 60019, Lapatinib, Lenalidomide, Leukeran, Lomustine, Melphalan, Methotrexate, Methylprednisolone, Mitomycin-C, Mitoxantrone, Moxifloxacin, Nilotinib, Nimdipine, Nimotuzumab, Obinutuzumab, Oxaliplatin, Paclitaxel, Pegfilgrastim, Pemetrexed, Penicillin , Pilocarpine, Prednisone, Regorafenib, Rituximab, Silver, Sorafenib, Sunitinib, Temozolomide, Tetracycline, Thiotepa, Timolol, Trastuzumab, Triamcinolone, Vancomycin, Vinblastine, Vincristine, Vinorelbine, or any combination thereof; antiglaucoma drugs; Nucleic acids, e.g., siRNA, shRNA, DNA, or any combination thereof; peptides, e.g., insulin, EGF, insulin aspart, insulin glulisine, insulin lispro, insulin degludec, insulin detemir, insulin glargine, or any combination thereof; proteins, e.g., TGF, gelatin, collagen, Trinectins, Interferons-α, -β, -γ, Interleukin, vaccine, Hepatitis B surface antigen, or any combination thereof; antibodies, e.g., cetuximab, OX26, transferrin, trastuzumab, infliximab, or any combination thereof; CRISPR/Cas9 agents or any combination thereof; other polymers, nanoparticles, nanofibers. dendrimers, polyethylene glycol, PLGA particles, PLA particles, chitosan, viral particles, iron oxide particles, gold particles, or any combination thereof; imaging agents; cells, e.g., T cells, dendritic cells, macrophages, monocytes, endothelial cells, epithelial cells, fibroblasts, or any combination thereof Combinations of any of the above are contemplated.

The active drug, other additive, or active substance mentioned above can be present in simple admixture with the composition and/or hydrogel, or may be present in solution or suspension or dispersion form together with the composition and/or hydrogel, or present in the composition and/or hydrogel in which the composition and/or hydrogel physically or chemically binds the drug, additive, or active substance in a matrix. Alternatively, the drug, other additive, or active substance can be covalently or ionically conjugated to the dendrimer and converted to hydrogel. For example, a camptothecin (CPT) dendrimer hydrogel preparation is contemplated.

The active drug, other additive, or active substance can be present in the composition and/or hydrogel in any amount suitable for its intended purpose. For example, the active drug, other additive, or active substance may be present in an amount ranging from 0.01 to 80% by weight of the composition and/or hydrogel, optionally including the solvent. This range includes all amounts and subranges therebetween, including 0.01, 0.02, 0.03, 0.04, 0.05, 0.06, 0.07, 0.08, 0.09, 0.1, 0.1, 0.2, 0.3, 0.4, 0.5, 0.6, 0.7, 0.8, 0.9, 0.1, 1, 2, 3, 4, 5, 6, 7, 8, 9, 10, 15, 20,25, 30, 35, 40, 45, 50, 55, 60, 65, 70, 75, 80% by weight, or any combination thereof.

### EXAMPLES

The following examples and others herein are provided for a better understanding of several embodiments, and are not intended to be limiting unless otherwise specified.

Materials and Methods

Materials. EDA-core PAMAM dendrimer generation 5 (G5) was purchased from Dendritech (Midland, Mich.). Polyethylene glycol diacrylate (PEG-DA, Mₙ=575 g/mol), acetic anhydride (Ac, 98.0%), triethylamine (TEA, 99%), 4′,6-diamidino-2-phenylindole (DAPI), fluorouracil (5-FU) and fluorescein 5(6)-isothiocyanate (FITC) were purchased from Sigma-Aldrich.

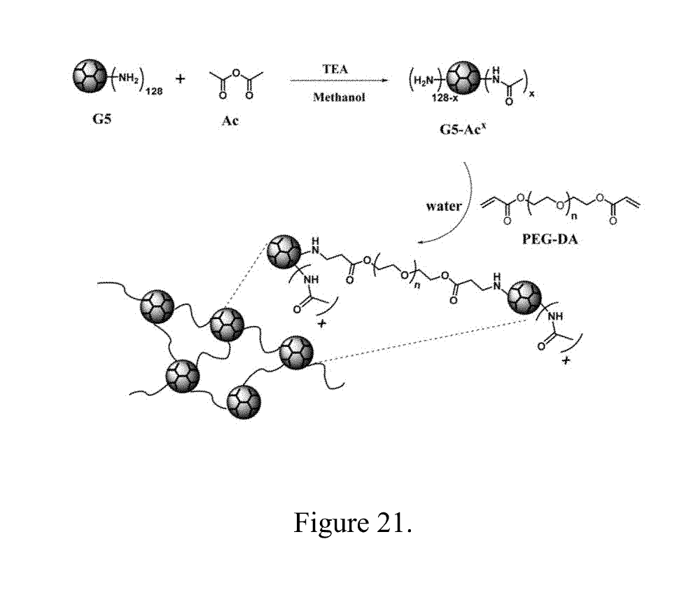

Synthesis and Characterization of Acetylated G5. Synthesis. Acetylated PAMAM dendrimers were synthesized following the reported procedures. Briefly, PAMAM dendrimer G5 (288 mg, 0.01 mmol) in 10 mL of methanol was mixed with various amounts of Ac in the presence of TEA (Table 2 and FIG. 21). FIG. 21 shows acetylated G5 (G %-Ac) synthesis and aza-Michael addition reaction of G5 or G5-Ac with PEG DA. After 12 h, the reaction mixtures were dialyzed in pH 8 sodium bicarbonate buffer and then in deionized water using SnakeSkin dialysis tubing (3.5K MWCO). After lyophilization, G5-Ac^{#} conjugates (# indicates an average of Ac per dendrimer determined by ¹H NMR) were obtained. FITC-labeled G5 and G5-Ac were also prepared following the protocol described previously.

TABLE 2
Reaction conditions for synthesis of acetylated G5.

| | Molar quantities of reactants (mmol) | | |
|---|---|---|---|
| G5-Ac^{x} | G5 | Ac | TEA |
| G5-Ac⁶⁴ | 0.01 (1 eq.) | 0.70 (70.4 eq.) | 0.88 (87.0 eq.) |
| G5-Ac⁹⁰ | 0.01 (1 eq.) | 0.97 (96 eq.) | 1.22 (121.6 eq.) |
| G5-Ac¹⁰⁶ | 0.01 (1 eq.) | 1.13 (112.6 eq.) | 1.41(140.8 eq.) |

^{a}determined by ¹H NMR spectroscopy.

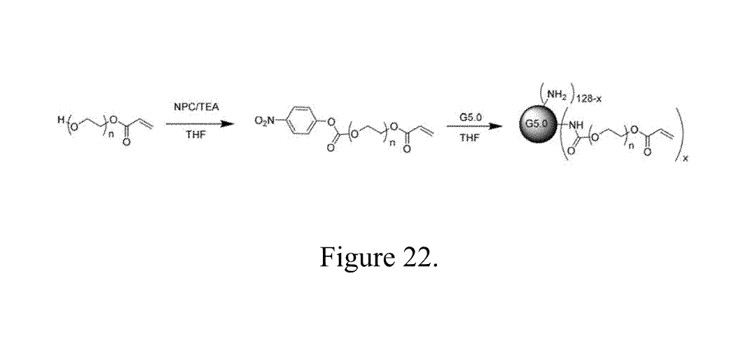

Another embodiment is shown in FIG. 22. In FIG. 22, hydroxyl PEG acrylate (1 equiv) was dissolved in tetrahydrofuran (THF), followed by addition of 4-nitrophenol chloroformate (NPC) (1.5 equiv) and triethylamine (TEA) (20 equiv). The reaction was run for 24 h at room temperature and the salt was filtered off The resulting acrylate PEG-NPC was collected by precipitation in diethyl ether and vacuum dried. PAMAM dendrimer G5.0 and acrylate PEG-NPC were dissolved in DMSO separately. The acrylate PEG-NPC solution was added dropwise to the dendrimer solution at various feed molar ratios for acrylate PEG-NPC:G5.0. After 72 h, the solvent was removed under vacuum. The resulting product G5.0-PEG acrylate was purified via dialysis in deionized water.

Proton Nuclear Magnetic Resonance (¹H NMR) Spectroscopy. ¹H NMR spectra of acetylated PAMAM dendrimers were obtained on a Bruker AV-III 400 MHz or a Bruker 600 MHz spectrometer. The degrees of acetylation were calculated based on the ratio of the integrals for methyl protons of acetyl groups to the dendrimer protons.

High Performance Liquid Chromatography (HPLC). The purity of acetylated G5 was determined by using a HPLC (Waters) system equipped with a Waters 1515 isocratic HPLC pump, a Waters 2487 dual λ, absorbance detector and a Waters 717 plus autosampler. The mobile phase was the mixture of acetonitrile and water (acetonitrile/water=3/1 by volume). The eluents were monitored by the UV detector at 220 nm and 360 nm.

Zeta Potential. The zeta potentials of the acetylated PAMAM dendrimers were characterized by using Malvern Zetasizer Nano ZS90 (Malvern Instruments, Worcestershire, U.K.).

Preparation and Characterization of Dendrimer Hydrogels. Formulations. PAMAM dendrimer (G5, G5-Ac⁶⁴, G5-Ac⁹⁰, or G5-Ac¹⁰⁶) was dissolved in deionized water or pH 7.4 PBS at 25° C. to have various concentrations (5, 10, or 20 wt. %). Appropriate amounts of PEG-DA 575 were added to maintain an equal molar ratio of acrylate to dendrimer surface primary amines in the solution. DH-G5-Ac^{x}-#% denotes dendrimer hydrogel (“DH”) where x is the number of the acetyl groups (“Ac”) and #% is the weight percentage of G5-Ac^{x} in solution. DH-G5-#% dendrimer hydrogels were also prepared at various concentrations. Inverted test tube method was applied to estimate dendrimer hydrogel solidification time, at which the gel does not flow in 30 s after the test tube is inverted. In this work, we tested hydrogel solidification time up to 100 min

Scanning Electron Microscopy (SEM). Lyophilized dendrimer hydrogel samples were coated with platinum for 90 seconds using an ion sputter. SEM images were taken under a scanning electron microscopy JEOL LV-5610.

Rheological Measurements. Rheological measurements were carried out on Discovery hybrid rheometer HR-3 (TA Instruments) and a 20 mm parallel plate geometry was used. Measurements were obtained at 25° C., which was achieved via a water bath and a temperature-controlled. Peltier plate. A small-amplitude dynamic oscillatory time sweep was conducted to examine the evolution of storage modulus (G′) and loss modulus (G″) and determine the sol-to-gel transition of the hydrogel solutions. During the small-amplitude dynamic oscillatory time sweep, the angular frequency was set to be 1 rad/s and the strain was kept constant as 1%. To conduct oscillatory frequency sweeps, an amplitude sweep (G′, G″ vs strain) was performed first to determine a linear viscoelastic region. Within the linear viscoelastic region, oscillatory frequency sweeps were then carried out under a constant strain of 1% in the frequency range of 0.1-10 rad/s.

Swelling Studies. Water absorption kinetics of dendrimer hydrogels (DH-G5-20%, DH-G5-Ac⁶⁴-20%, and DH-G5-Ac⁹⁰-20%) was determined. Each lyophilized hydrogel was immersed and incubated in 1 mL of PBS (pH=7.4) at 37° C. The supernatant was gently sucked out at different time intervals and the swollen hydrogel sample was weighed. The measurement period was up to 12 h in order to reach the maximum absorption. The swelling ratio (%)=(Wₜ−W₀)/W₀×100, where Wₜ represents the mass of the swollen sample and W₀ represents the initial mass of the dry sample.

Disintegration Studies. The disintegration properties of dendrimer hydrogels (DH-G5-20%, DH-G5-Ac⁶⁴-20%, DH-G5-Ac⁹⁰-20%, and DH-G5-Ac¹⁰⁶-20%) was determined at 37° C. Each lyophilized hydrogel was weighted and incubated at 37° C. in 1.5 mL-centrifuge tubes containing 500 μL of PBS (pH=7.4). After 6 h, 24 h, and 48 h, respectively, the samples were centrifuged and the sample residues were freeze-dried and weighed. The disintegration was calculated based on the following formula: disintegration (%)=(W_{d0}−W_{dt})/W_{d0}×100 where W_{dt} represents the mass of the freeze-dried sample after incubation and W_{d0} represents the initial mass of the dry sample.

Cell Adhesion Studies. To examine whether dendrimer hydrogel supports cell attachment, 2.5 μL/well of FITC labeled dendrimer hydrogel DH-G5(FITC)-Ac⁶⁴-10% was added to the 96-well plate and shaken for 24 h to form a thin layer of DH at the bottom of the well. NIH3T3 cells were then seeded on the hydrogel with a density of 1×10⁴ cell/well. After 24 h and 48 h, respectively, the cell culture medium was removed and the cells were fixed and stained with DAPI and imaged under a fluorescence microscope (Nikon Eclipse Ti) under DAPI and FITC channels. A control experiment without DH was carried out by seeding cells directly on the tissue culture polystyrene plate (TCPS). In addition, to prove the stability of DH during the cell attachment and growth, three letters ‘VCU’ were written with DH-G5(FITC)-Ac⁶⁴-10% and incubated in the culture medium at 37° C. for either 24 h or 48 h. The letters were imaged to monitor the stability of the hydrogel. Cell viability after 24 h and 48 h-culture on the hydrogel was independently determined by using WST-1 assay.

Liquid Dendrimer Hydrogel Loaded with 5-FU. A liquid dendrimer hydrogel, i.e., DH-G5-0.5% was used to load anticancer drug 5-FU and the formulation was examined for drug delivery in vitro and in vivo.

In Vitro Drug Release Kinetics. Drug release was performed on 5-FU loaded into DH-G5-0.5% (5-FU/DH-G5-0.5%). Briefly, Free 5-FU (300 μg) in PBS or DH-G5-0.5% containing 300 μg of 5-FU was transferred to dialysis bags (MWCO=500-1000 Da) and suspended in 30 mL of PBS in 50-mL centrifuge tubes. The tubes were maintained at 37° C. At predetermined time intervals up to 24 h, 1 mL of medium outside the dialysis bag was withdrawn, and the amount of drug released into the medium was analyzed on HPLC against a standard curve of 5-FU. After each sampling, 1 mL of fresh PBS was added to maintain a constant volume and sink condition. All experiments were performed in triplicate.

Cytotoxicity Assessment. To study the cytocompatibility of DH-G5-0.5%, NIH3T3 fibroblasts were seeded in a 96-well plate at a density of 1×10⁴ cell/well. After 24 h of cell attachment, the culture medium was replaced by 200 ₗtL of medium containing DH-G5-0.5% at different concentrations. Cell viability after 24 h-and 48 h-incubation was determined by using WST-1 assay.

In Vivo Formulation Toxicity and Drug Efficacy Studies. Female athymic nude mice (4-6 weeks-old, 18-20 g, Harlan Sprague-Dawley, Indianapolis, Ind.) were used in the study. HN12 head and neck cancerous cells (5×10⁶ cells/ml) in 200 μL of PBS were injected into the dorsal subcutaneous tissue of host mice to induce tumor xenografts. Two weeks later, the tumor-bearing mice were divided into four groups of three to receive intratumoral injection of PBS, DH-G5-0.5%, 5-FU/PBS, or 5-FU/DH-G5-0.5%. Injection solution volume was 2.5 mL/kg, and 5-FU dose was 5 mg/kg for the first injection and then 10 mg/kg at later time points. Tumor volume and body weight of tumor-bearing mice were monitored throughout the experiment. Tumor volume (Vₜ) was calculated with the formula: V₁=width²×length/2. Relative tumor volume at different time point was calculated by normalized to the initial tumor volume: Relative tumor volume=Vₜ/V₀, where V₀ represents the initial tumor volume. At the end of experiment, the mice were euthanized and tumors were dissected out for hematoxylin and eosin (H&E) staining The animal experiments were approved by the Institutional Animal Care and Use Committee of Virginia Commonwealth University.

Statistical Analysis. The data were analyzed by using unpaired t-test and one way analysis of variance (ANOVA). P values less than 0.05 were considered statistically significant.

Results and Discussion

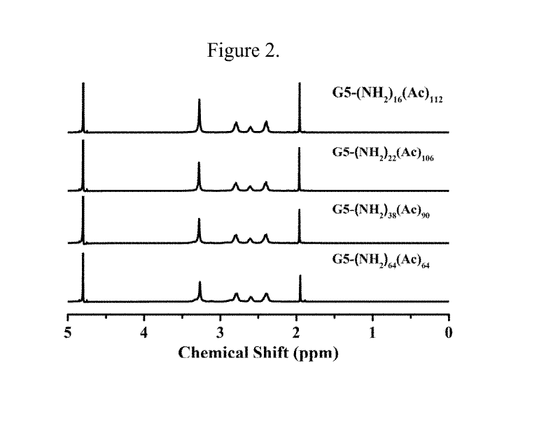

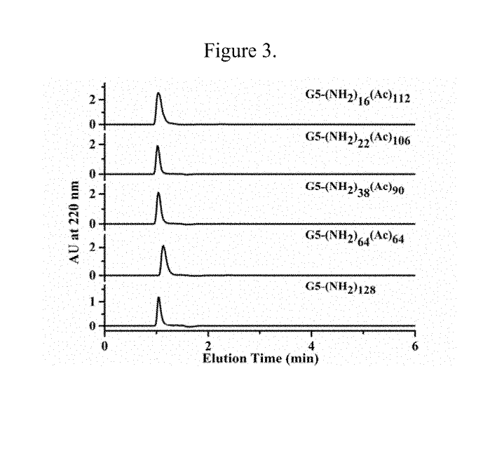

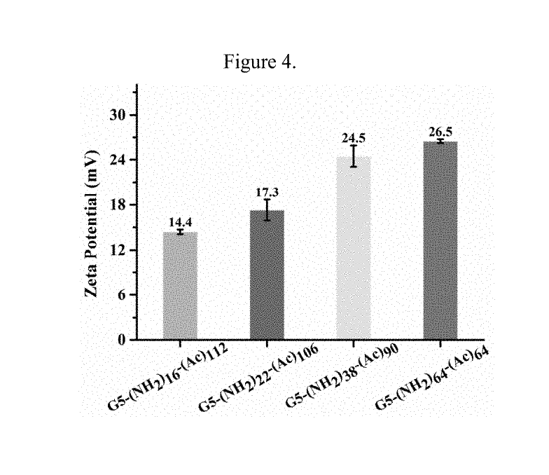

The degrees of acetylation calculated from 1H NMR results are listed in FIG. 2. The HPLC spectra in FIG. 3 show a high purity for all acetylated G5 dendrimers. As shown in FIG. 4, with the decrease of acetylation, the amine groups of G5 PAMAM dendrimers increase and the zeta potentials tend to increase.

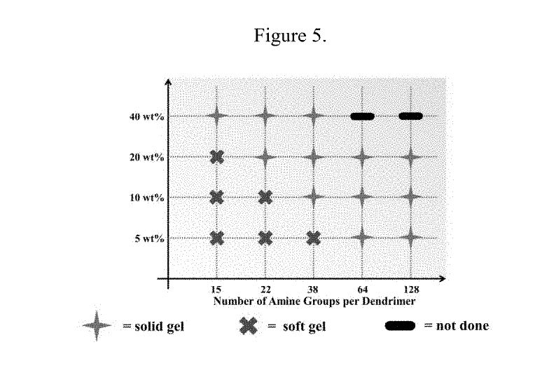

The G5 PAMAM dendrimer with five different degrees of acetylation can form either a solid hydrogel or a soft gel after reacting with PEG diacrylate575 under different concentrations, which is summarized in FIG. 5. Dendrimers with higher concentration and/or with more amine groups tend to form a solid gel.

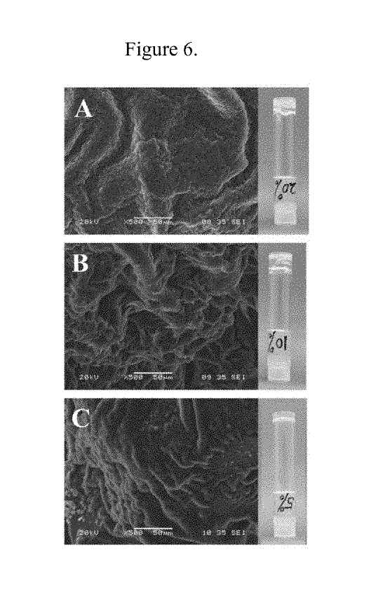

With the decrease of the dendrimer concentration, the morphologies of the three-dimensional network differ from each other, see FIG. 6A-C. The dendrimer possessing a higher concentration shows a more compact network structure.

With the decrease of the amine groups on the surface of the dendrimer, the morphologies of the three-dimensional network differ from each other. The dendrimer possessing more amine groups shows a more compact network structure.

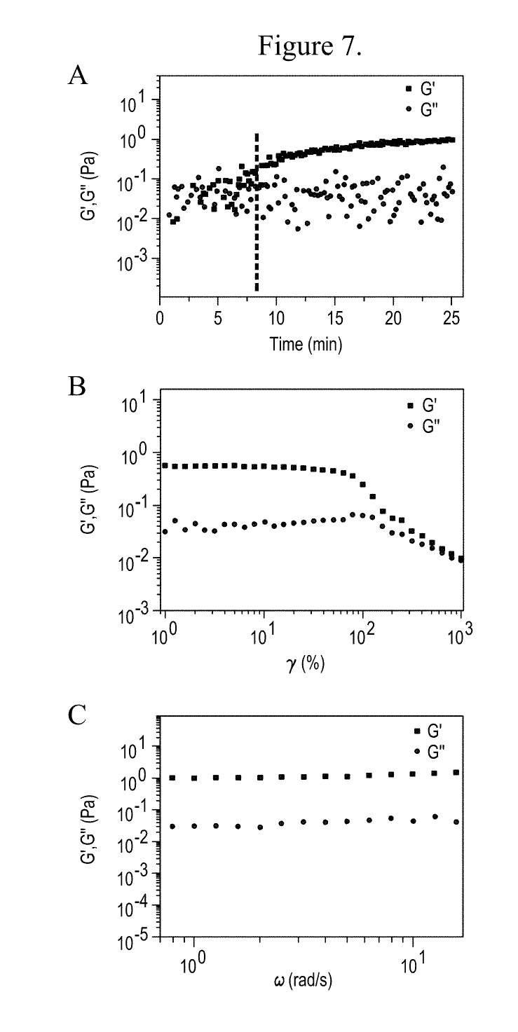

The time sweep rheological experiment shows that the gel point is at about 7 min for the 5 wt % of dendrimer solution, see FIG. 7A. This rapid gelation is due to the highly efficient reactivity of the Michael-addition chemistry. The amplitude sweep and frequency sweep in FIGS. 7B and C both demonstrate the elastic behavior of the hydrogel. Especially in FIG. 7C, the elastic modulus (G′) is frequency-independent and higher than viscous modulus (G″), which indicate that it is a classic viscoelastic gel.

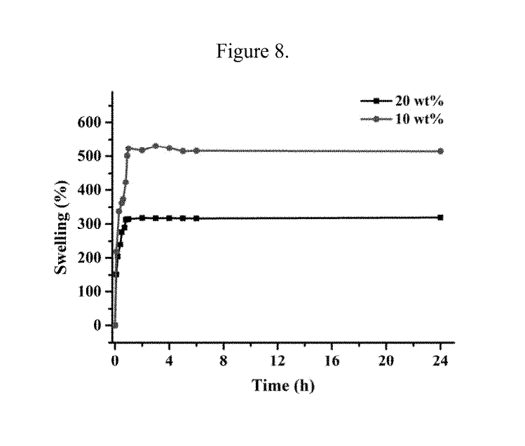

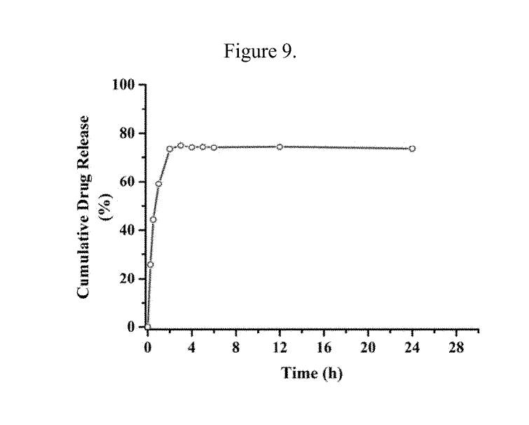

As the dendrimer possessing a higher concentration shows a more compact network structure, the equilibrium swelling is also higher, as shown in FIG. 8. The high gelation efficiency of this dendrimer hydrogel makes it an ideal in-situ drug loading and delivery system. We physically embedded an anti-cancer drug of fluorouracil in the dendrimer hydrogels and tested its release behaviors, as shown in FIG. 9. It shows a rapid release at the first 3 hours and about 70% of the drug has been released and then the release reaches equilibrium.

We also fabricated dendrimer hydrogels which are comprised of generation 3 polyamidoamine (G3 PAMAM) dendrimers and G3.5 PAMAM with the surface modified to have some PEG acrylate chains (G3.5-PEG-acrylate). The synthetic routes for G3.5-PEG-acrylate are shown in FIG. 20. The gelation solvent is water and gelation temperature is 25° C.

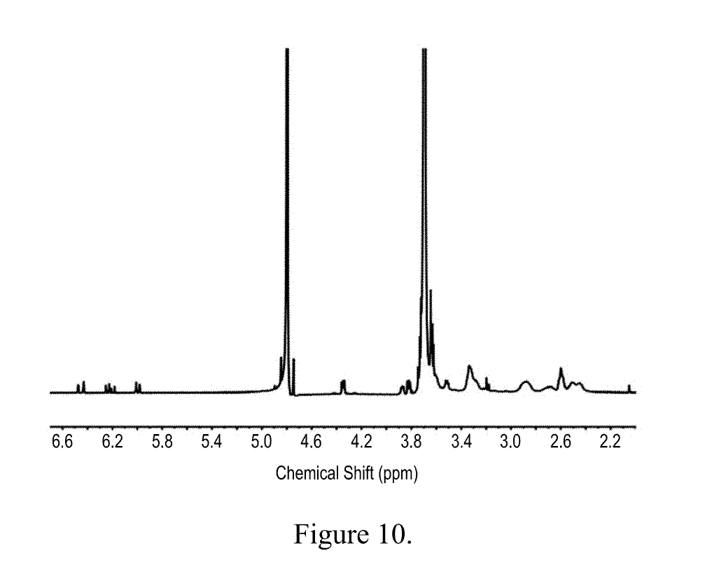

From the 1H NMR spectra of the obtained G3.5-PEG-acrylate in FIG. 10, it can be calculated that there are about 27 of PEG acrylate grafted onto the surface of every dendrimer molecule.

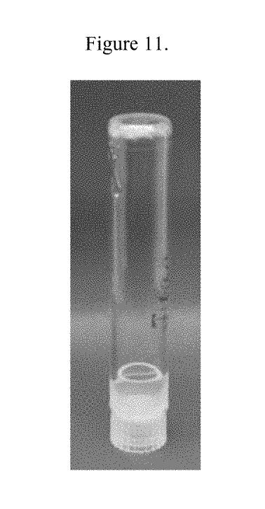

FIG. 11 shows a photo of invert gel fabricated from G3.5-(PEG1500-acrylate)27 and PAMAM G3. The concentration of the G3.5-(PEG1500-acrylate)27 is 20 wt % and the feed ratio of the amine groups and acrylate groups is 1 to 1.

Acetylation of G5. The aza-Michael addition reaction is one of the most exploited reactions to form carbon-nitrogen bonds in organic chemistry. Full generation PAMAM dendrimers contain numerous primary amines on the surface and secondary amines in the core. These strong nucleophilic amines present in the dendrimer backbone can react with a, 3-unsaturated ester in acrylate group of PEG DA via aza-Michael addition reaction to form a cross-linked network. Despite the fact that original secondary amines are more reactive than primary amines in the aza-Michael addition reaction, their availability to the reaction is low due to steric hindrance. Therefore, the reaction predominantly utilizes the primary amines on the dendrimer surface. Converting surface amines to non-reactive acetyl groups provides a means to modulate reaction kinetics and cross-linked network. To this end, G5-Ac conjugates with various degrees of acetylation were synthesized. The purity of the acetylated PAMAM dendrimers was verified with the HPLC analysis. The ¹H NMR spectra confirm the presence of the methyl protons of the conjugated acetyl groups at 1.96 ppm and the peak intensity increases with increasing degree of acetylation. Based on the integrals of methyl protons of acetyl groups to the dendrimer protons (peaks at 3.28, 2.80, 2.61, and 2.39 ppm), an average of 64, 90, and 106 acetyl groups were coupled to the dendrimer, respectively. Unmodified PAMAM G5 has a zeta potential of 50.03 mV. The zeta potential of G5-Ac conjugates decreases with increasing acetylation degree, but all remain positive. Since PAMAM dendrimer G5 surface property was altered by converting primary amines into acetyl groups, G5 functionalized with different degrees of acetylation were utilized to modulate in situ gelation kinetics of dendrimer hydrogels.

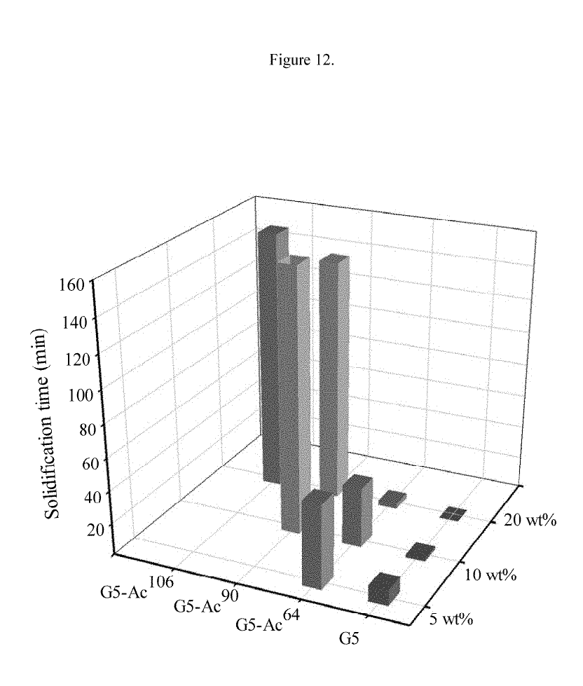

Tunable Hydrogel Solidification. The aza-Michael addition reaction of G5 or G5-Ac with PEG-DA occurred at room temperature in the absence of any other reagents. An inverted test tube method was applied to detect the flow properties of the hydrogels and estimate solidification time. To study aza-Michael addition reactions of dendrimer and PEG DA under relatively controllable conditions, we chose degree of acetylation and dendrimer concentration as primary variables and kept equal molar quantities of dendrimer primary amines and PEG acrylate groups in the reactions. The aza-Michael addition reaction was able to proceed under the conditions studied. As shown in FIG. 12, both degree of acetylation and dendrimer concentration affect solidification kinetics. However, not all of dendrimer hydrogels underwent sol-gel phase transition to solidify. Those having high degrees of acetylation either only formed liquid hydrogels or required much longer time to solidify at low concentrations. They were not included in the figure. Within the observation time window, DH-G5-Ac⁹⁰ solidified at 10 and 20 wt %. But DH-G5-Ac¹⁰⁶ solidified only at 20 wt %. In contrast, lower degree of acetylation and higher dendrimer concentration enable dendrimer hydrogels to solidify more rapidly. At 20%, DH-G5, DH-G5-Ac⁶⁴, DH-G5-Ac⁹⁰ and DH-G5-Ac¹⁰⁶ were able to solidify. Solidification times were 1 min, 4 min, 146 min, and 158 min, respectively. Both DH-G5 and DH-G5-Ac⁶⁴ solidified at even lower concentrations at 5 wt % and 10 wt % but took longer time. For instance, solidification time of DH-G5 at 10 wt % was 2.5 min and was further extended to 11 min when the concentration was reduced to 5 wt %.

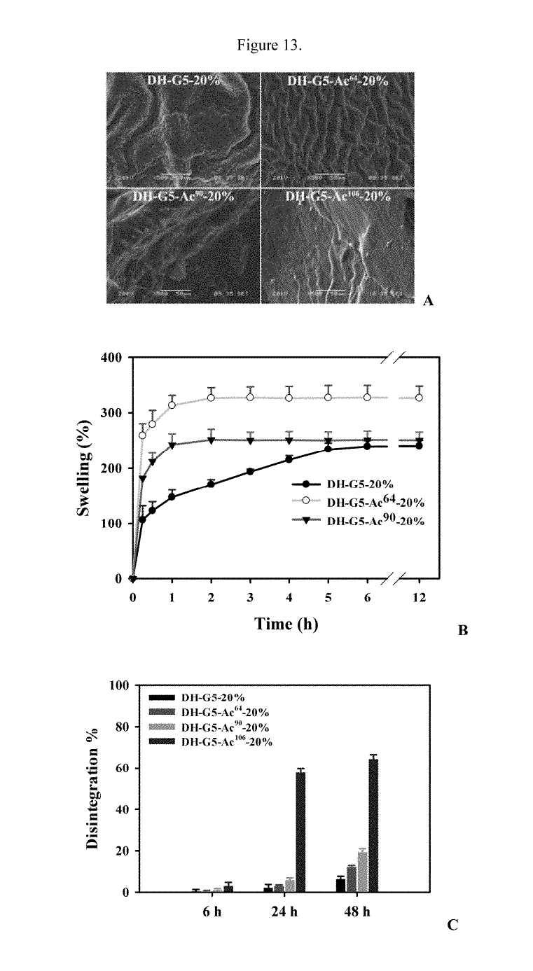

Effect of Acetylation on Swelling and Disintegration Behaviors. Given that DH-G5 and DH-G5-Ac regardless of degree of acetylation were able to solidify at 20 wt %, we examined their morphologies and the effect of degree of acetylation on hydrogel swelling and disintegration. As shown in FIG. 13A, dendrimers with more amine groups tended to form more compact hydrogels with rough microstructures while those with less amine groups showing a loose and smooth structure. The formation of dense microstructures is attributed to the high density of cross-linking sites. Their swelling behaviors were examined in pH 7.4 PBS at 37° C. The swelling kinetics of DH-G5-Ac¹⁰⁶-20% was not obtained as it was unstable and started to disintegrate after 6 h. As for DH-G5-20%, DH-G5-Ac⁶⁴-20% and DH-G5-Ac⁹⁰-20%, the dehydrated samples showed a rapid swelling rate in the first 0.25 h and absorbed 107%, 259%, and 182% of its own weight of PBS, respectively. The swelling then gradually reached equilibrium (FIG. 13B).

Interestingly, the swelling rate of DH-G5-20% was significantly lower than the other two DHs. It took DH-G5-20% 6 h to reach its equilibrium, ˜240%, while it took DH-G5-Ac⁶⁴-20% and DH-G5-Ac⁹⁰-20% only 2 h to reach equilibrium swelling ratios (˜326% for DH-G5-Ac⁶⁴-20% and 250% for DH-G5-Ac⁹⁰-20%). In addition, DH-G5-Ac⁶⁴-20% and DH-G5-Ac⁹⁰-20% exhibited the highest and lowest equilibrium swelling ratio, respectively. The different swelling ratios and rates may be attributed to the 3-D cross-linked structures of the hydrogel. Generally speaking, a loose cross-linked network allows more PBS to be absorbed into the swollen hydrogel, and at the same time the swelling rate would be higher. This explains why the equilibrium swelling ratio of DH-G5-Ac⁶⁴-20% is higher than that of DH-G5-20% and why DH-G5-20% has the lowest swelling rate. As for DH-G5-Ac⁹⁰-20%, the most loosely cross-linked structure is a double-edged sword. Although its more porous structure tends to absorb more PBS, the lowest cross-linking density leads to an unstable architecture that is insufficient maintaining the absorbed PBS.

The disintegration behaviors of DH-G5-20%, DH-G5-Ac⁶⁴-20%, DH-G5-Ac⁹⁰-20%, and DH-G5-Ac¹⁰⁶-20% were also investigated and the results are shown in FIG. 13C. All the four DHs were stable within 6 h since no more than 3% of mass loss was observed. Except for DH-G5-Ac¹⁰⁶-20%, the other three DHs could maintain their structural integrity within 24 h with no more than 6% of mass loss. DH-G5-¹⁰⁶-20% experienced 60% and 64% of mass loss at 24 h and 48 h, respectively. At 48 h, DH-G5-20%, DH-G5-Ac⁶⁴-20%, and DH-G5-Ac⁹⁰-20% lost 7%, 12%, and 19% of mass, respectively. It seemed that the acetylation of G5 accelerated and aggravated the disintegration of the DHs. The weak alkaline of dendrimer and the aqueous proton buffer were the key triggers for accelerated degradation of ester bond. As dendrimer concentration was kept the same for all the DHs, the aqueous proton buffer became the dominant factor for disintegration kinetics. DH fabricated from highly acetylated G5 tended to form a loose network structure. A loose network architecture means quicker buffer absorption, which in turn, accelerates the disintegration of the hydrogel structure.

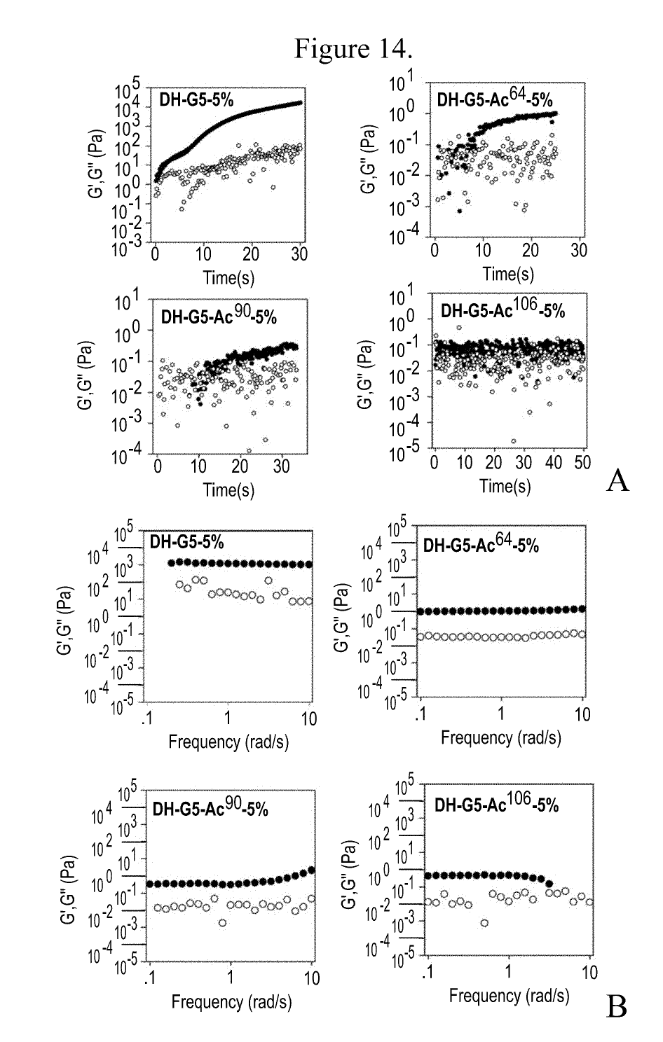

Tunable Rheological Properties. An oscillatory time sweep was performed for G5-Ac^{x}-5% and PEG-DA mixtures to monitor the evolution of storage modulus (G′) and loss modulus (G″). For a typical hydrogel formulation, in the early stage, G″ is higher than G′, indicating the viscous property of a sol state. When G′ exceeds G″, it indicates a gel forms and the elastic property dominates. The intersection between G′ and G″ reflects the sol-to-gel transition. As shown in FIG. 14A, G′ is higher than G″ at the beginning and there is no intersection of G′ and G″. That is presumably because the gelation occurred so quickly that the sol-to-gel transition had completed prior to the measurement. The sol-to-gel transition of DH-G5-Ac⁶⁴-5% and DH-G5-Ac⁹⁰-5% occurred at 5-7 min and 10-20 min, respectively. As for G5-Ac¹⁰⁶-5%, it did not show any obvious changes of G′ and G″ within 50 min. It is worth noting that after the gelation point, G′ was still increasing. That means that the gelation point shown in a time sweep only indicates an effective network forms at this point and elastic property dominates henceforth. The formation of a completely cross-linked network would require a longer time. This explains why the gelation times obtained from the time sweep of DH-G5-5%, DH-G5-Ac⁶⁴-5% and DH-G5-Ac⁹⁰-5% were less than that observed in the invert tube method (FIG. 12). However, both time sweep and inverted test tube method agreed well on that acetylation would extend the gelation time.

To further demonstrate the 3-dimensional structure of the hydrogels, the oscillatory frequency sweep was performed on all the samples. Before the frequency sweep, an amplitude sweep was carried out to make sure that the measurement was in the linear viscoelastic region. As shown in FIG. 14B, G′ was higher than G″ for all the samples. G′ was frequency-independent over the entire measured frequency range for DH-G5-5% and DH-G5-Ac⁶⁴-5% and at lower frequency range for DH-G5-Ac⁹⁰-5% and DH-G5-Ac¹⁰⁶-5%. The frequency-independency of G′ and G′>G″ were typically viscoelastic behavior of hydrogel. DH-G5-5% and DH-G5-Ac⁶⁴-5% form stable network structures because of the high density of amine groups on the dendrimer surface. As for DH-G5-Ac⁹⁰-5% and DH-G5-Ac¹⁰⁶-5%, higher frequency affects their further confirming their network structures are relatively less stable. G′ of DH-G5-5% (˜10³ Pa) was much higher that G′ of DH-G5-Ac⁶⁴-5%, DH-G5-Ac⁹⁰-5% and DH-G5-Ac¹⁰⁶-5% (˜10⁰ Pa). The highest cross-linked density of DH-G5-5% was attributed to its highest elasticity. In summary, by changing the degree of acetylation of G5, one can easily tune the cross-linking density of the DHs and modulate their gelation time and rheological properties.

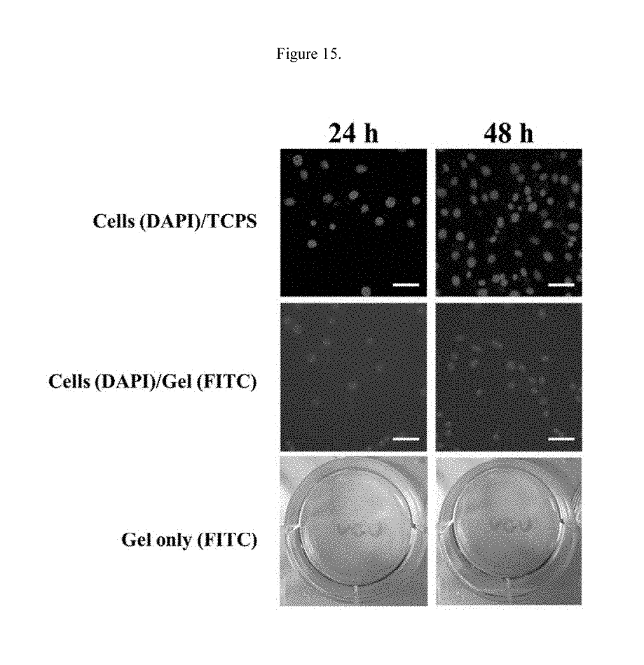

Solidified Dendrimer Hydrogel Supports Cell Adhesion and Growth. To study the cell attachment and proliferation on the dendrimer hydrogel, FITC-labeled DH-G5-Ac⁶⁴-10% was used because of its good cytocompatility and ability to form solidified gel in situ in a short time (solidification time 38 min) for possible cell attachment. Cell culture and proliferation on TCPS was included as control. As shown in FIG. 15 (middle panel), NIH3T3 cells can adhere to and grow on the hydrogel substrate. The cells were counterstained with DAPI and colocalized with FITC-stained hydrogel substrate. More cells were found at 48 h, indicating their proliferation despite at a lower rate than those on TCPS. The letters ‘VCU’ written using DH-G5(FITC)-Ac⁶⁴-10% after 24 h and 48 h incubation further confirmed the stability of this dendrimer hydrogel during the cell culture. WST-1 assay showed that the hydrogel was well tolerated by the cells and did not reduce cell viability. Cell attachment is attributed in large part to the positive charge, surface microstructure, and structural stability of the dendrimer hydrogel.

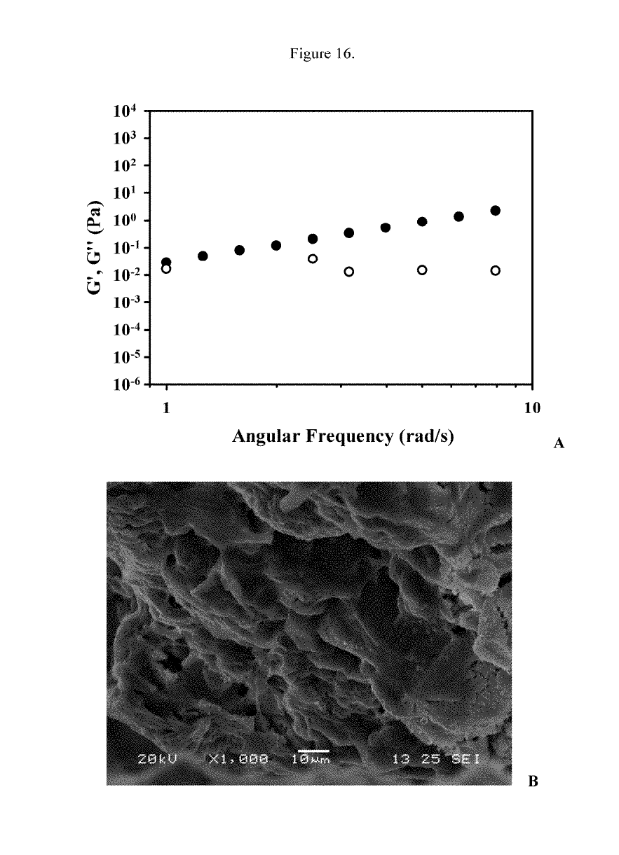

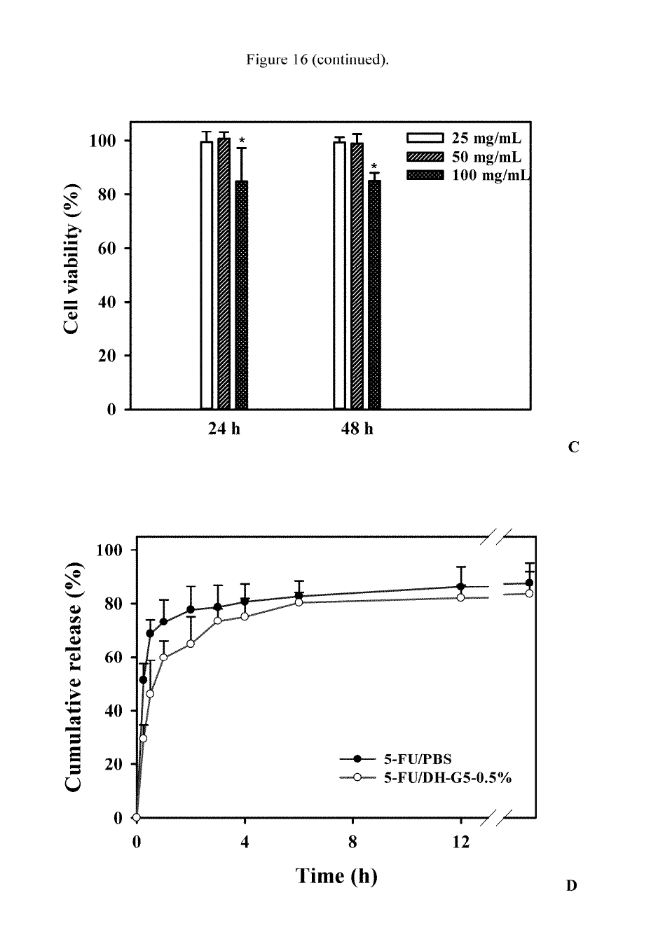

Liquid Dendrimer Hydrogel for Drug Delivery. DH-G5-0.5% was selected to formulate an injectable drug/hydrogel formulation for intratumoral anticancer drug delivery. The frequency sweep of DH-G5-0.5% (FIG. 16A) confirmed that it formed a stable liquid hydrogel as its G′ was greater than its G”. The SEM image shown in FIG. 16B illustrates its network structure. Compared to the other formulations, DH-G5-0.5% can remain its fluidity. The fluidity of the formulation makes intratumoral injection more operable. A low concentration of G5 in the formulation would avoid the risk of causing cumulative toxicity to the tissue. Cytotoxicity study revealed that DH-G5-0.5% is highly cytocompatible. It did not cause toxicity effects up to 50 mg/mL (equivalent to 250 μg/mL of G5) following 24-h or 48 h-exposure (FIG. 16C). When the concentration was doubled, only less than of 20% reduce in cell viability was observed. 5-FU can be slowly released from DH-G5-0.5% (FIG. 16D). An initial burst release followed by sustained release was observed for both 5-FU/PBS and 5-FU/DH-G5-0.5%. However, DH-G5-0.5% extended the duration of both burst release and sustained release. Nearly 70% of 5-FU was released within just 0.5 h from the PBS control group and then quickly reached a plateau of 80% in 2 h. In contrast, the release of 5-FU from DH-G5-0.5% was prolonged. About 60% of 5-FU was released from DH-G5-0.5% within 1 h and a longer time (6 h) was spent before the cumulative release plateau of 80% was reached. In the formulation of 5-FU/DH-G5-0.5%, part of 5-FU was complexed with dendrimers via electrostatic and hydrophobic interactions, whereas the rest of 5-FU was loosely entrapped in the hydrogel network. The burst release within 1 h was due to the release of 5-FU in the gel network. The following sustained release was caused by the diffusion of 5-FU from the interior of dendrimer. The release test demonstrated that such a low viscous liquid hydrogel is still capable of slowly releasing drug. The injectability, biocompatibility and sustained drug release made DH-G5-0.5% a suitable formulation for intratumoral drug delivery test.

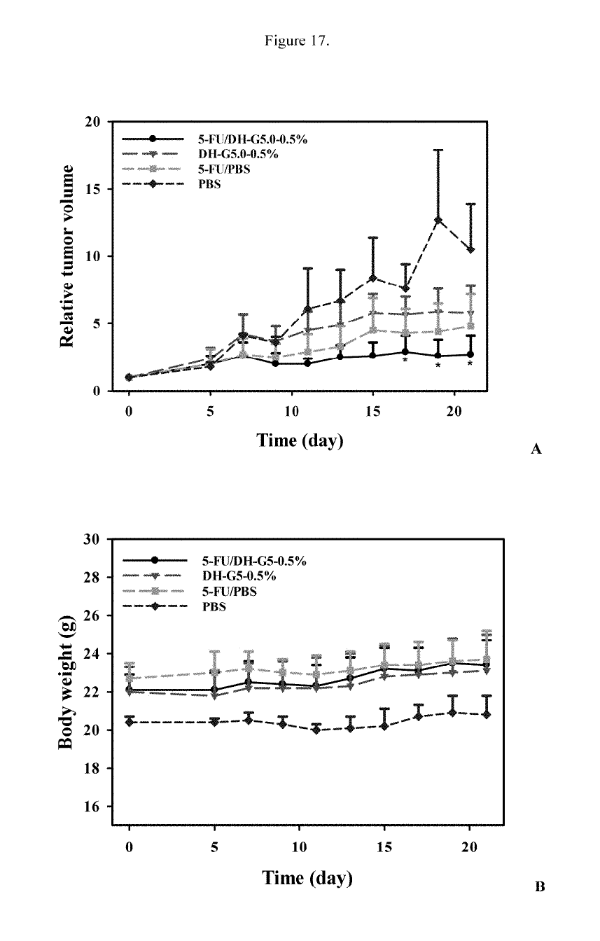

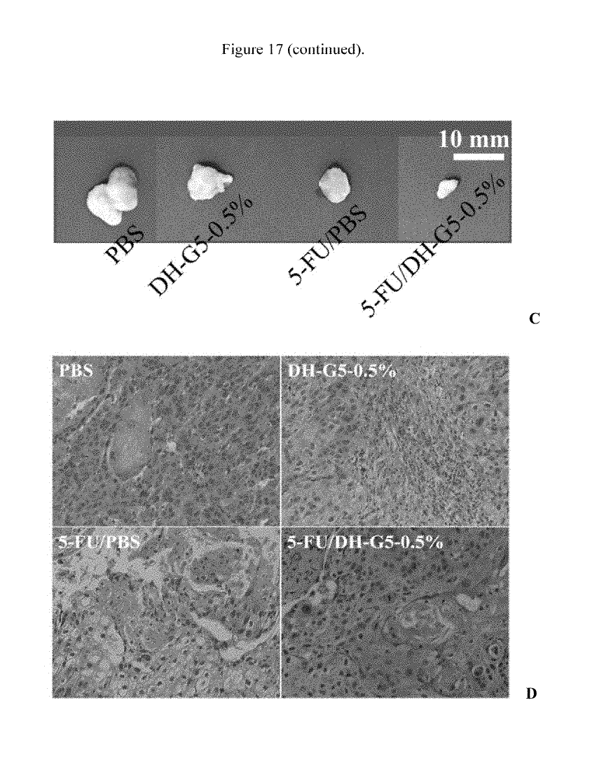

Solid tumors such as head and neck cancer are accessible and can benefit from localized chemotherapy for stronger antitumor effects and less systemic toxicity. We tested this new drug formulation in a head and neck cancer model via intratumoral injection and compared it with 5-FU/PBS. 5-FU/PBS did not show significant tumor inhibition effects. In contrast, 5-FU/DH-G5-0.5% shows a strong trend inhibiting tumor growth (FIG. 17A). The tumor volume became significantly lower than the rest treatment groups at day 17. Compared to the terminal tumor volume of the PBS group, 5-FU/DH-G5-0.5% reduced tumor volume by 4 folds, indicating that the drug/dendrimer hydrogel formulation promoted significantly better in vivo anticancer efficacy. The body weight of the tumor-bearing mice was also monitored. There was no obvious loss of body weight for the mice during the treatment (FIG. 17B). The end-point tumor images (FIG. 17C) further illustrate the significantly reduced tumor size by 5-FU/DH-G5-0.5%. H&E staining (FIG. 17D) shows that 5-FU/DH-G5-0.5% resulted in high massive tumor cell remission. Furthermore, the H& E staining did not reveal any morphological change in the blank hydrogel group, indicating the nontoxicity of the hydrogel itself Taken together, injectable dendrimer hydrogel provides a sustained drug delivery platform for localized chemotherapy.

A novel type of PAMAM dendrimer hydrogel was successfully developed based on aza-Michael addition chemistry. The solidification time, rheological behavior, network structure and swelling property of the hydrogel can be modulated by adjusting dendrimer surface acetylation degree and dendrimer concentration. In addition, the new PAMAM dendrimer hydrogels have good biocompatibility and support cell adhesion and proliferation. The dendrimer hydrogel can be utilized to prepare injectable drug formulations for localized chemotherapy. This hydrogel with tunable properties prepared by aza-Michael addition reaction can serve as a new platform for drug delivery and tissue engineering.

The present invention has been described with reference to particular embodiments having various features. In light of the disclosure provided above, it can be apparent to those skilled in the art that various modifications and variations can be made in the practice of the present invention without departing from the scope or spirit of the invention. One skilled in the art can recognize that the disclosed features may be used singularly, in any combination, or omitted based on the requirements and specifications of a given application or design. When an embodiment refers to “comprising” certain features, it is to be understood that the embodiments can alternatively “consist of” or “consist essentially of” any one or more of the features. Other embodiments of the invention can be apparent to those skilled in the art from consideration of the specification and practice of the invention.

It is noted in particular that where a range of values is provided in this specification, each value between the upper and lower limits of that range is also specifically disclosed. The upper and lower limits of these smaller ranges may independently be included or excluded in the range as well. The singular forms “a,” “an,” and “the” include plural referents unless the context clearly dictates otherwise. It is intended that the specification and examples be considered as exemplary in nature and that variations that do not depart from the essence of the invention fall within the scope of the invention. Further, all of the references cited in this disclosure are each individually incorporated by reference herein in their entireties and as such are intended to provide an efficient way of supplementing the enabling disclosure of this invention as well as provide background detailing the level of ordinary skill in the art.

1. A method of forming a dendrimer hydrogel, the method comprising:
providing one or more amine end-functioned polyamidoamine (PAMAM) as a first reactant;
providing one or more small molecule, polymer, hyperbranched molecule, or dendrimer as a second reactant, wherein the second reactant comprises one or more acrylate groups; and
reacting the first reactant with the second reactant by way of conjugate addition.

2. The method of claim 1, wherein the conjugate addition is Michael-addition.

3. The method of claim 1, wherein the first reactant and the second reactant are reacted in the presence of a protic solvent or an aprotic solvent.

4. The method of claim 1, wherein the reacting is performed at a temperature ranging from −20-50° C.

5. The method of claim 1, wherein the reacting is performed in the presence of water and at a temperature of about 25° C.

6. A method of forming a dendrimer hydrogel, the method comprising:
providing one or more amine end-functioned polyamidoamine (PAMAM);
providing one or more poly(ethylene glycol) (PEG) diacrylate; and
reacting the PAMAM with the PEG diacrylate by way of conjugate addition.

7. The method of claim 1, wherein the conjugate addition is Michael-addition.

8. A method of forming a dendrimer hydrogel, the method comprising:
providing one or more first reactant which is a polyamidoamine (PAMAM) chosen from PAMAM G5-(NH2)x-(Ac)128-x, wherein x is a number ranging from 1 to 128;
providing one or more second reactant which is a compound comprising one or more acrylate groups; and
performing a conjugate addition reaction with the first and second reactant to produce a dendrimer hydrogel.

9. The method of claim 1, wherein the first reactant and the second reactant are soluble in water.

10. The method of claim 1, wherein the second reactant, the compound comprising one or more acrylate groups, is poly(ethylene glycol) (PEG) diacrylate: 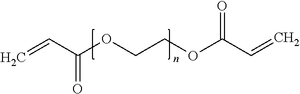
wherein n is 8 or 9.

11. The method of claim 10, wherein the PEG diacrylate is PEG diacrylate 575, a PEG diacrylate having a number average molecular weight (Mn) of 575.

12. The method of claim 1, wherein the first reactant, the polyamidoamine, is PAMAM G5-(NH2)16-(Ac)112 or PAMAM G5-(NH2)22-(Ac)106 or PAMAM G5-(NH2)38-(Ac)90 or PAMAM G5-(NH2)64-(Ac)64 or PAMAM G5-(NH2)128.

13. The method of claim 1, wherein the second reactant, the compound comprising one or more acrylate groups, is poly(ethylene glycol) (PEG) diacrylate: 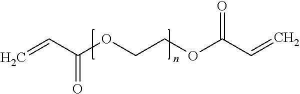
wherein n is 8 or 9; and
conjugate addition is performed in the presence of a protic solvent and at a temperature ranging from −20-50° C.

14. The method of claim 3, wherein the protic solvent is water and the temperature is about 25° C.

15. The method of claim 1, wherein amine groups and acrylate groups are present in a ratio of 1 to 1.

16. The method of claim 1, wherein the second reactant has a degree of functionality with respect to acrylate groups that is larger than or equal to 2.

17. A method of forming a dendrimer hydrogel, the method comprising:
reacting in the presence of water at a temperature of about 25° C.:
polyamidoamine PAMAM G3-(NH2)32; with
PAMAM G3.5-(PEG1500-acrylate)27;
to form a dendrimer hydrogel.

18. A method of treating cancer, the method comprising administering to a patient a compound, such as a drug, wherein the drug is administered using a dendrimer hydrogel as a drug delivery vehicle and the hydrogel comprises the following structure:

[symbol]

19. A composition comprising:
a compound, such as a drug; and
a dendrimer hydrogel as a drug delivery vehicle for the drug, wherein the hydrogel comprises the following structure:

[symbol]

20. The composition of claim 19, wherein the compound, such as a drug, is chosen from one or more of:
abiraterone, bevacizumab, bortezomib, cetuximab, chlorambucil, cytotoxan, etopisode, gleevec, ibrutinib, imatinib, irinotecan, lenalidomide, leukeran, obinutuzumab, pegfilgrastim, rituximab, trastuzumab; and/or
altretamine, busulfan, carboplatin, carmustine, chlorambucil, cisplatin, cyclophosphamide, dacarbazine, lomustine, melphalan, oxaliplatin, temozolomide, thiotepa; and/or
5-fluorouracil (5-FU), 6-mercaptopurine (6-MP), capecitabine, cytarabine, floxuridine, fludarabine, gemcitabine, hydroxyurea, methotrexate, pemetrexed; and/or
daunorubicin, doxorubicin, epirubicin, idarubicin; and/or
actinomycin-D, bleomycin, mitomycin-C, mitoxantrone; and/or
docetaxel, estramustine, ixabepilone, paclitaxel, vinblastine, vincristine, vinorelbine; and/or
prednisone, methylprednisolone, examethasone.
